(19) United States
(12) Patent Application Publication
(10) Pub. No.: US 2006/0113612 A1
(43) Pub. Date: Jun. 1, 2006

(54) Insulated-gate semiconductor device and approach involving junction-induced intermediate region

(76) Inventors: Kailash Gopalakrishnan, Mountain View, CA (US); James D. Plummer, Portola Valley, CA (US)

Correspondence Address: CRAWFORD MAUNU PLLC, 1270 NORTHLAND DRIVE, SUITE 390, ST. PAUL, MN, 55120, US

(21) Appl. No.: 10/518,779

(22) PCT Filed: Jun. 19, 2003
(86) PCT No.: PCT/US03/19279

§ 371 Date: Jun. 6, 2005

(30) Foreign Application Priority Data
Jun. 19, 2002 (US) 60390821

(51) Int. Cl. H01L 29/94

(52) U.S. Cl. 257/392

(57) ABSTRACT

Semiconductor device performance is improved via an insulated-gate PIN-type structure that is adapted to abruptly switch between conductance states by modulating an electric field in the intermediate (I) region. According to an example embodiment of the present invention, an insulated gate-type structure includes a body with first and second end regions and an intermediate region coupled therebetween, the intermediate region having a length defined by junctions at the first and second regions. The first and second end regions have opposite polarizations and the intermediate region has a polarization that is neutral relative to the polarizations of the first and second end regions. The insulated gate-type structure also includes a gate that is coupled to the intermediate region and adapted, with the intermediate region, to apply an electric field nearer one of the two junctions. With the body reverse biased, the electric field can be modulated to switch the structure between a stable state and a current-conducting state in which an avalanche breakdown occurs in the intermediate region.

### FIELD OF THE INVENTION

The present invention relates generally to semiconductor devices and more specifically to semiconductor devices having a reverse-biased multi-region body having oppositely doped end regions on either side of an intermediate region and having a gate structure used to facilitate current switching.

### BACKGROUND OF THE INVENTION

Recent technological advances in the semiconductor industry have permitted dramatic increases in circuit density and complexity, and commensurate decreases in power consumption and package sizes for integrated circuit devices. Single-chip microprocessors now include many millions of transistors (e.g. bipolar junction transistors (BJT) and metal oxide semiconductor (MOS) devices) operating at speeds of hundreds of millions of instructions per second to be packaged in relatively small, air-cooled semiconductor device packages. A by product of these technological advances has been an increased demand for semiconductor-based products, as well as increased demand for these products to be fast, reliable, flexible to manufacture and inexpensive. These and other demands have led to increased pressure to manufacture a large number of semiconductor devices at an efficient pace while increasing the complexity and improving the reliability of the devices.

One important circuit component that affects the control and the performance of semiconductor devices is the electrode, such as a gate electrode. Polysilicon is one example material that has long been used as the gate electrode of MOS devices, such as MOS Field-Effect Transistors (MOSFETs), with this type of device also being referred to as an insulated-gate (capacitively-coupled) FET (“IGFET”). To increase the carrier concentration in the polysilicon electrode, the polysilicon is typically doped very heavily to be either N-type or P-type.

The threshold voltage of a MOSFET is related to the difference between the workfunctions of the gate electrode and the channel region of the MOSFET. With a fixed workfunction for the gate material, the MOSFET threshold voltage has typically been adjusted by choosing the dopant concentration in the silicon below the gate dielectric (e.g., in the channel region). To achieve this, a technique such as ion implantation is used to introduce a specific amount of dopant with desired depth profile in the channel region (this is sometimes referred to as the “threshold-adjustment implant”).

As transistors and other FET-type device are scaled smaller, the voltage supplied to the device has a relatively increased affect on certain performance aspects of the device. For instance, higher voltage generally relates to higher dynamic power dissipation per device and correspondingly higher overall dynamic power dissipation of the chip in which the device is employed. The dynamic power dissipation is given, for example, by C_{TOT}×V_{DD}×ΔV_{DD}×f, where C_{TOT} is the total switching capacitance, ΔV_{DD} is the swing at the outputs and f is the frequency of operation. In addition, higher voltage also generally relates to larger electric fields within the device, which can sometimes adversely affect the reliability of the operation of the device. In this regard, the supply voltage for devices being scaled smaller is desirably reduced. However, this reduction in supply voltage affects the ability of the device to maintain current in its ON-state; namely, the threshold voltage for maintaining current must still be met. Scaling of the threshold voltage, however, is challenging for a variety of reasons. For instance, such scaling is limited by leakage in the sub subthreshold region (i.e., voltages below the threshold voltage).

In devices like the MOSFET, BJT, etc., this subthreshold leakage current is dominated by diffusion of carriers from the source or emitter respectively. One important characteristic of the subthreshold regime is its steepness or nonlinearity with respect to the gate voltage. As a rule, the higher this nonlinearity, the lower the leakage current. A dimensionless measure of nonlinearity (with respect to the gate voltage, V_{G}) is as follows:

$$\begin{matrix}( Equation 1 ) & \\ N ( {V}_{G} ) = \frac{\frac{{\partial }^{2} {I}_{D}}{{\partial }^{2} {V}_{G}}}{\frac{\partial {I}_{D}}{\partial {V}_{G}}} . & ( 1 )\end{matrix}$$

The aforementioned diffusion limited process has a nonlinearity (i.e., N(V_{G})) which is limited to q/kT or around 40/V (at room temperature)). This means that decreasing threshold voltages lead to increasing leakage currents through these devices because the inverse subthreshold slope (the slope of a plot of the amount of current passed in the device versus gate voltage) is limited to a thermodynamic value of kT/q or 60 mV/decade at about room temperature. This contributes to increased static power dissipation in chips and also reduced retention time in memories (e.g., DRAM).

These and other considerations have presented challenges to the implementation and advancement of switching circuitry, and in particular for low-power, highly-reliable circuitry.

### SUMMARY

Various aspects of the present invention are directed to a semiconductor device having an insulated-gate adapted to manipulate an electric field in the intermediate region of a body having oppositely-doped regions on each side of the intermediate region. These and other aspects of the present invention are exemplified in a number of illustrated implementations and applications, some of which are described in the following detailed description.

According to an example embodiment of the present invention, a semiconductor device comprises a multi-region body including a first region dominated by a first polarization that extends to a first junction, a second region dominated by an opposite polarization that extends to a second junction, and an intermediate region having a length extending from the first junction to the second junction. The device also includes a gate that is capacitively-coupled to the multi-region body and adapted for using a control signal when the multi-region body is reversed biased, to modulate an electric field in the intermediate region.

According to another example embodiment, the present invention is directed to a P-I-N (P+ region/intermediate region/N+ region) device having an insulated gate adapted to permit the gate voltage to manipulate the electric-field in the intermediate region. The respective ion concentrations in the oppositely-doped regions are sufficiently large relative to the intermediate region to define metallurgical junctions between each oppositely-doped region and the intermediate region. In this context, a metallurgical junction refers to a junction that defines an abrupt transition from a region heavily doped to achieve one polarity (P+ or N+) to a region where this heavy doping abruptly disappears, this latter region being either intrinsic or lightly doped (p or n). With a voltage applied to the gate when the P-I-N device is reversed biased, the effective length of the intermediate region can be changed relative to its the actual length (between the metallurgical junctions), for example, to set up or remove set up for an avalanche voltage breakdown condition, or to cause an avalanche voltage breakdown condition.

According to yet another embodiment, the present invention is directed to a memory circuit including a data storage node, a multi-region body passing current to and/or from the data storage node, and a gate capacitively-coupled to the multi-region body. The multi-region body includes a first region dominated by a first polarization that extends to a first junction, a second region dominated by an opposite polarization that extends to a second junction, and an intermediate region having a length extending from the first junction to the second junction. The gate is coupled to the body via an intervening dielectric material and is offset for using a control signal, when the body is reversed biased, to present an electric field substantially at only one of the first and second junctions. The body responds to the electric field by switching from a stable conductance state to a current-conducting state in which the body is in an avalanche breakdown condition and current passes between the data storage node and the body.

Other aspects of the present invention are directed to various operational modes and structures that are largely consistent with the above embodiments, and to methods for manufacturing such structures. With the approaches discussed above, challenges such as reducing power supply voltage, reducing dynamic power dissipation, maintaining electric fields and others including those discussed above are addressed. In addition, these approaches facilitate the integration of an increasingly larger number of transistors at increasing clock frequencies at a relatively modest increase in overall dynamic power dissipation of a circuit employing these devices. Leakage is inhibited while realizing relatively high performance and similar dynamic power dissipation, for instance, as compared to conventional CMOS and other devices. Furthermore, current switching between an OFF state (e.g., reversed-biased, high resistance) and an ON state (i.e., low resistance as exhibited during avalanche breakdown) is effected at a relatively rapid rate.

According to a more particular example embodiment, a memory device includes an impact-ionization type device having a subthreshold slope significantly lower than kT/q leading up to a threshold voltage required for current switching. The device may be implemented with a wide variety of circuit structures, for example, such as for storing data at a node coupled for maintaining a charge. The data storage is controlled as a function of a threshold voltage applied for controlling the conductance state of the device. With this approach, the threshold voltage required for effecting current switching can be reduced without necessarily significantly affecting current flow, relative to the threshold voltage-current relationship for conventional transistors with higher subthreshold slopes. Furthermore, this reduction in threshold voltage is achieved while maintaining acceptable levels of leakage during an off (current-blocking) state, effecting rapid switching and data transfer with low power consumption.

The above summary is not intended to describe each illustrated embodiment or every implementation of the present invention. The figures and detailed description that follow more particularly exemplify these embodiments.

### BRIEF DESCRIPTION OF THE DRAWINGS

The invention may be more completely understood in consideration of the detailed description of various embodiments of the invention that follows in connection with the accompanying drawings, in which:

FIG. 1A shows a cross-sectional view of an insulated gate device, according to an example embodiment of the present invention;

FIG. 1B shows a cross-sectional view of an insulated gate device, similar to that shown in FIG. 1A and having a step region, according to an example embodiment of the present invention;

FIG. 2 shows current versus gate voltage for an insulated gate device such as that shown in FIG. 1A, according to another example embodiment of the present invention;

FIG. 3 shows current flow in an intermediate region of an insulated gate device, according to another example embodiment of the present invention;

FIG. 4 shows current flow in an intermediate region of an insulated gate device, according to another example embodiment of the present invention;

FIG. 5 shows two modes of operation of an insulated gate device, with each mode corresponding, for example, to current flow as shown in FIGS. 3 and 4, respectively, according to another example embodiment of the present invention;

FIG. 6A shows an arrangement of an insulated gate device, according to another example embodiment of the present invention;

FIG. 6B shows an arrangement of an insulated gate device, according to another example embodiment of the present invention;

FIG. 7A shows an inverter, according to another example embodiment of the present invention;

FIG. 7B shows transient operation of the inverter shown in FIG. 7A, according to another example embodiment of the present invention;

FIG. 8 shows another insulated gate device in a silicon-on-insulator (SOI) structure, according to another example embodiment of the present invention;

FIG. 9 shows current versus voltage for an insulated gate on SOI, such as that shown in FIG. 8, according to another example embodiment of the present invention;

FIG. 10 is a memory circuit, according to another example embodiment of the present invention;

FIG. 11A is a dual-gate device, according to another example embodiment of the present invention;

FIG. 11B is another dual-gate device, according to another example embodiment of the present invention;

FIG. 12 is a FIN-type device, according to another example embodiment of the present invention; and

FIG. 13 shows a pass circuit with two insulated gate devices, according to another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is believed to be applicable to a variety of different types of semiconductor devices, and the invention has been found to be particularly suited for devices in the deep-sub-micron regime, such as MOS devices and other field-effectable structures adapted to respond to a voltage at its capacitively-coupled gate by accumulating carriers under the gate and forming an accumulation surface channel. While the present invention is not necessarily limited to such applications, various aspects of the invention may be appreciated through a discussion of various examples using this context.

According to an example embodiment of the present invention, an insulated-gate device includes an intermediate region defined by metallurgical junctions (as described above) and between two oppositely-doped regions. The oppositely-doped regions have a relatively high dopant concentration (e.g., one being N+ and the other P+), while the intermediate region is relatively neutral (e.g., intrinsic, lightly p-doped or lightly n-doped). With the oppositely-doped regions reversed biased, a voltage is presented to the insulated gate to form an accumulation surface channel in the intermediate region with carriers flowing as defined by the polarity of the reversed-biased oppositely-doped regions. The concentration of accumulated carriers is strongest near the metallurgical junction where the gate-induced field is strongest. Moving across the intermediate region and away from this gate-induced field, the carrier flow disperses and thereby creates a field-induced junction in the intermediate region. With the device still being reverse biased, this field-induced junction effectively moves the distance between the metallurgical junctions and thereby reduces the effective length of the intermediate region over which the potential across the two oppositely-doped region drops.

For such a P-I-N (P+ region/intermediate region/N+ region) device, the respective dopant concentrations in the oppositely-doped P+ and N+ regions are sufficiently large relative to the intermediate region to define the metallurgical junctions and to permit the gate voltage to manipulate the electric-field in the intermediate region. For example, using conventional MOS source/drain terminology, the oppositely-doped regions are P+ and N+ source/drain regions relative to an intrinsic or lightly-doped (P or N) intermediate region. The gate-induced electric field is created in a portion of the intermediate region nearest only one of the metallurgical junctions. In a planar structure, for example, this arrangement can be realized by offsetting the gate toward one side of the intermediate region so that the gate-induced electric field is created over one metallurgical junction. With this arrangement, the gate exhibits, at most, negligible influence over the other metallurgical junction. In another example embodiment, this electric-field discrimination is realized by changing the work function of the gate in order to maximize the gate-induced electric field over one metallurgical junction and to minimize the gate-induced electric field over the other metallurgical junction.

According to another aspect of the present invention, the P-I-N device is adapted with the intermediate region having sufficient actual length for exhibiting an avalanche breakdown before punch through (e.g., tunneling) breakdown.

This type of P-I-N device is controlled to achieve various modes of operation according to different aspects of the present invention. For instance, a first low-resistance state (e.g., an “ON” state) is realized by applying a positive voltage to the insulated gate concurrent with the reverse-biased condition. The ensuing electric field creates a field-induced junction in the intermediate region so as to effectively move the near metallurgical junction and decrease the effective length of the intermediate region over which the potential across the two oppositely-doped region drops. This phenomena renders the device more susceptible to an avalanche voltage-breakdown condition. Further increasing (or concentrating) the energy (for example, via the relative voltages at the device's insulated gate and its oppositely-doped regions) causes avalanche breakdown, and the device abruptly switches from a high (reverse-biased) resistance state to this first ON state in which significant current flows from the negatively doped region to the positively doped region.

A second ON state is realized by applying a negative voltage to the insulated gate to force the device into an avalanche voltage-breakdown condition. The negative voltage at the gate accumulates holes (rather than electrons) in a surface channel portion. The ensuing field-induced junction created in the intermediate region effectively moves the far metallurgical junction closer to the near metallurgical junction to decrease the effective length of the intermediate region across which the potential between the oppositely-doped regions drops.

As with the first ON state, this phenomena also renders the device more susceptible to a voltage-breakdown condition. Further increasing the electric field causes avalanche breakdown, and the device abruptly switches from a high (reverse-biased) resistance state to this second ON state in which significant current flows from the negatively doped region to the positively doped region.

Another low resistance state is realized by forward biasing the device. For example, by controlling the voltage at one or both of the oppositely-polarized regions, sufficient energy can be concentrated in the intermediate region to switch the device to the conventional forward biased condition.

The above discussion of various ON conditions suggests that the device can be operated in multiple high-resistance states (“OFF” states). For instance, just before avalanche breakdown as discussed above, the device is in a reverse-biased state in which drift current (leakage) between the oppositely-doped regions is slightly higher than the earlier reverse-biased state. In the earlier reverse-biased state, the effective length of the intermediate region (over which the potential across the two oppositely-doped region drops) is the distance between the two metallurgical junctions defining the intermediate region.

The present invention also contemplates other stable (ON or OFF) as well as non-stable states. For instance, another OFF state is established when the device's terminals are controlled to avoid being in both the forward-biased condition and the reverse-biased condition. In another example embodiment, the PIN device includes an internal feedback loop and/or a built-in gain mechanism that enhances the nonlinearity of the device, for instance, as discussed in connection with Equation 1 above. In this context, the length of the intermediate region is also modulated before a breakdown condition or leading to a breakdown condition. Various other stable and non-stable states include manipulating the electric field within the intermediate region (via gate-controlled modulation and/or adjusting the voltage(s) at one or more of the device's terminals) to cause the device to move closer to or further from the above-discussed ON and OFF states.

Accordingly, by manipulating the electric field within the intermediate region, the effective length of the intermediate region is modulated and the P-I-N device can be used to switch the device between conductance states in an abrupt manner. Advantageously, this operation can be implemented to achieve a subthreshold slope that is lower than kT/q. This subthreshold slope represents a change in current per a corresponding change in voltage, i.e., such that an increase in voltage results in a relatively small increase in current in this instance.

In one implementation, the subthreshold slope for switching conductance states of the P-I-N is significantly less than kT/q at room temperature for a conventional CMOS device (e.g., significantly less than about 60 mV/decade). In various other implementations, the subthreshold slope is less than about 30 mV/decade, 20 mV/decade 10 mV/decade and 5 mV/decade, respectively. With these implementations, the insulated gate device has been found particularly useful for applications requiring rapid switching, such as memory and logic applications.

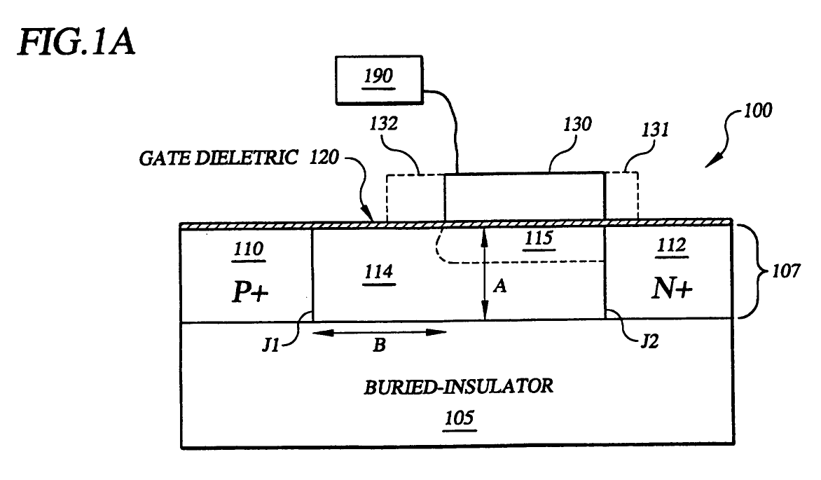

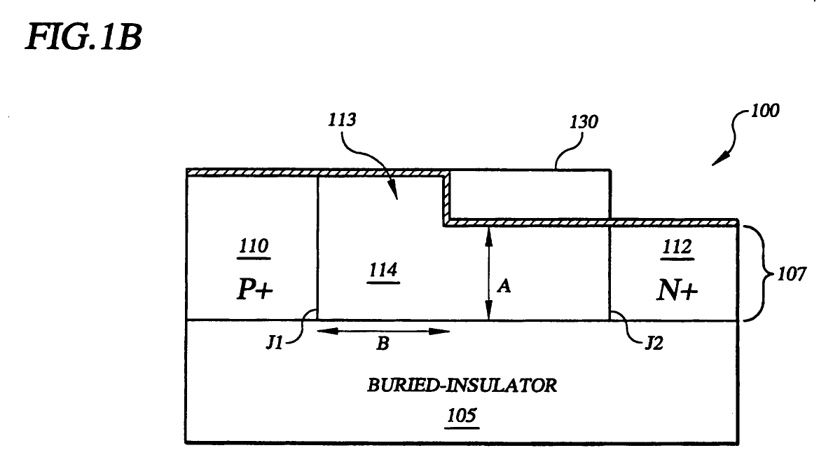

FIG. 1A shows a cross-section of an insulated gate device 100, according to another example embodiment of the present invention. The device 100 includes a substrate region 107 on a buried insulator layer 105, the substrate region including a multi-region body: a P+ doped circuit region 110; an N+ doped circuit region 112; and an intermediate region 114 separating the circuit regions 110 and 112. The intermediate region 114 includes one or more portions that are intrinsic (e.g., undoped) and/or lightly doped, relative to the circuit regions 110 and 112. The dopant concentration (or lack thereof) of the intermediate region 114 is selected depending upon various factors including, for example, the application for which the device 100 is implemented, the respective dopant concentrations of the circuit regions 110 and 112 (relative to the dopant concentrations of the intermediate region 114) that define the metallurgical junctions denoted as J1 and J2, and whether counter-doping is used and in which case the intermediate region 114 would likely bear at least the first type of dopant species. A gate dielectric 120 is formed over the intermediate region 114 in the substrate 107, and a gate electrode 130 is formed on the gate dielectric 120. The gate electrode includes, for example, a conductive material such as metal, N+ polysilicon and/or P+ polysilicon.

The gate electrode 130 is offset between the metallurgical junctions J1 and J2 to present an initial electric field substantially at only one of the two metallurgical junctions, in this example embodiment, only at J2. Use of “substantially” in this context acknowledges that there may be some small electric field that reaches the other junction but does not create an initial accumulation surface channel). In a particular example application, the gate electrode 130 slightly overlaps, or about overlaps, the region 112, and the distances “A” (the thickness of the intermediate region 114) and “B” (the distance laterally separating the gate electrode 130 from the circuit region 110) are about equal; in one example application, these distances are about 25 nanometers. In response to a voltage applied at the gate electrode 130, an electric field is modulated in the intermediate region 114, thereby creating or altering a field-induced junction in the intermediate region 114. With the P+ region being held at a lower voltage than the N+ region to reverse bias the this multi-region body, the field-induced junction is used to set-up the previously-discussed breakdown condition, and current flow between N+ region 112 and the P+ region 110 is thus controlled.

Depending upon various characteristics, such as dopant concentrations, temperature and application to which the device is applied, control for current switching with the device 100 is effected in a variety of manners. In one implementation, the operation of the device 100 includes the N+ region 112 being held at V_{DD} (high potential, e.g., between about 0.25 and 100V) and the P+ region 110 being held at low potential (e.g., ground). A relatively high positive voltage, greater than the threshold voltage (V_{T}, e.g., between about 0.1V and 50V) necessary for causing breakdown in the intermediate region 114 is applied to the gate 130, accumulating N-type carriers below the gate in the intermediate region. The influenced carriers expand beyond an accumulated surface channel under the gate 130 and create a vertically-oriented field-induced junction under the gate. This modulated carrier presence effectively moves the N+ region 112 closer to the P+ region 110, reducing the distance across which the potential between the N+ region 112 and the P+ region 110 drops (i.e., the effective length of the intermediate region 114). This reduction in effective length increases (or concentrates the electric fields across which this potential drops which, in turn, leads to a breakdown condition in the intermediate region 114 in which the device 100 passes current.

When implemented for logic circuitry using an approach (as shown) which is more analogous to the operation of an NMOS device, voltage levels for a particular example mode of operation include holding the P+ region 110 at about zero volts (ground), holding the N+ region 112 between zero volts and V_{DD} (e.g., with V_{DD} between about 0.5 and 1.5 V) and implementing the device so that it exhibits a V_{T} of between about 0.1 and 0.3V. In an ON state, V_{DD} is greater than the gate voltage (V_{G}) which is greater than V_{T}. In the OFF state, V_{G} is less than V_{T}.

When implemented using a PMOS type approach (as discussed below, with the gate 130 located closer to the P+ region 110), the signs of the voltages are changed (to negative levels).

In another particular example embodiment, the device 100 further includes a controller 190 electrically coupled to the gate 130 and adapted to apply a signal thereto for controlling an avalanche condition in the intermediate region 114. In one implementation, the controller 190 includes a gain mechanism adapted to effect a nonlinear response of current flow in the device 100, relative to voltage applied to the gate 130. In another implementation, the controller 190 is coupled to one or more circuits in a feedback loop and is adapted to apply a feedback signal to the gate 130 in response to feedback from the circuit(s) to which it is coupled. For instance, by coupling the controller 190 to the P+ region 110 or the N+ region 112, a feedback signal is obtained and used to effect current flow in the device 100 in response to the feedback signal and any other voltage applied to the gate 130. In one particular implementation, the controller 190 applies the voltage to the gate electrode 130 for controlling current flow in the intermediate region 114, with the voltage being applied as a function of the feedback and/or the gain mechanism.

The lateral position of the gate 130 relative to the P+ region 110 and N+ region 112 is selectable for a variety of implementations. In one instance, the gate 130 is aligned over the N+ region 112 and overlapping an interface between the N+ region and the intermediate region 114, as shown by dashed line 131. With this approach, a voltage applied to the gate 130 also couples to the N+ region 112 and therein affects the concentration of carriers near the gate (depleting or accumulating, with negative and positive voltages, respectively). In another instance, the gate 130 extends closer to the P+ region 110, as shown by dashed line 132, such that the distance “B” is reduced. With this approach, the gate 130 couples to a relatively wider portion of the intermediate region 114 (for example, to create a longer carrier channel region). When a positive voltage is applied to the gate 130, this relatively longer carrier channel region creates a correspondingly shorter region across which the potential between the P+ region 110 and N+ region 112 drops. With a shorter distance for the potential drop, the electric field in the portion of the intermediate region 114 defined by the distance “B” is increased, causing the device 100 to enter a breakdown state in which current flows.

In another more particular implementation, a portion 115 of the intermediate region 114 below the gate is doped N-type, with the application of a high voltage to the gate 130 creating a channel in the N-type portion 115. With this approach, a lower voltage level is needed to shorten the effective length of the intermediate region 114 between the N+ region 112 and the P+ region 110 over which potential drops. Correspondingly, the electric field in the intermediate region 114 is increased and a breakdown occurs.

According to the present invention, the device 100 in FIG. 1A is implemented in a variety of circuits and applications including but not limited to data storage (such as registers and memory cells) and logic devices (e.g., replacing FET devices). In one example implementation involving both data storage and logic, the device 100 replaces one or more MOSFET-type transistors that are arranged to provide bit-line access to a memory cell, for example, in a SRAM, DRAM or FLASH device. In one such implementation providing access as part of a six-transistor cell, the device 100 replaces one or more FETs with a bit line coupled to the N+ region 112 and a word line coupled to the gate 130. With this approach, the device 100 limits leakage current in its current blocking mode and increases performance via its ability to switch abruptly to (and from) its low-resistance conducting state.

In other example implementations, the device 100 in FIG. 1A is manufactured using one or more of a variety of approaches to arrive at the shown physical device characteristics. For example, conventional masking and ion-implanting steps can be used to form the P+ doped region 110 and N+ doped region 112. In one instance, the gate 130 is used as a mask for self-aligning the N+ doped region 112 thereto such that the gate is immediately adjacent J2. In another instance, a sidewall spacer (not shown) is formed immediately adjacent a vertical sidewall portion of the gate 130 facing the P+ region 110. The width of the sidewall spacer is such that a subsequent P+ ion implant forms P+ region 110 aligned to J1, while inhibiting the P+ implant from implanting the intermediate region 114. In still another instance, as discussed above in connection with the counter-doping approach, a portion of the intermediate region 114 and the P+ region 110 are concurrently lightly doped. The intermediate region 114 is then masked, the mask is patterned (e.g., using photolithography) and the P+ region 110 is counter-doped to the P+ concentration, using the patterned mask for alignment to form J1 as shown. For general information regarding semiconductor manufacturing processes, and for specific information regarding masking, implanting and other approaches that may be implemented in connection with one or more example embodiments discussed herein, reference may be made to Wolf et al., “Silicon Processing for the VLSI Era,” Vol. 1, Chapters 9 and 12-14 (Lattice Press, 1986), which is fully incorporated herein by reference.

FIG. 1B shows a cross-section of another insulated gate device, similar to the device shown in FIG. 1A (and having its articles labeled similarly), according to another example embodiment of the present invention. In this example, the intermediate region 114 includes an extended portion 113 laterally adjacent to the gate 130, with a corresponding portion of the P+ region 110 also extending upward, relative to similar features of the device shown in FIG. 1A. The extended portion 113 is formed to a height that enables hot carrier cooling (relaxation of energy), prior to the hot carriers reaching an upper surface of the device. The height reduces the potential for high energy (hot) carriers to reach the upper surface. For instance, the height of extended portion 113 (shown here being about equal to the height of the gate 130) may be in the range of about 5 nanometers to many microns to achieve this. In one particular implementation, the height of the extended portion 113 is between about 50 and 100 nanometers when used in connection with the device shown exhibiting an electron energy relaxation length (e.g., length across which hot carriers cool) on the order of about 100 Angstroms.

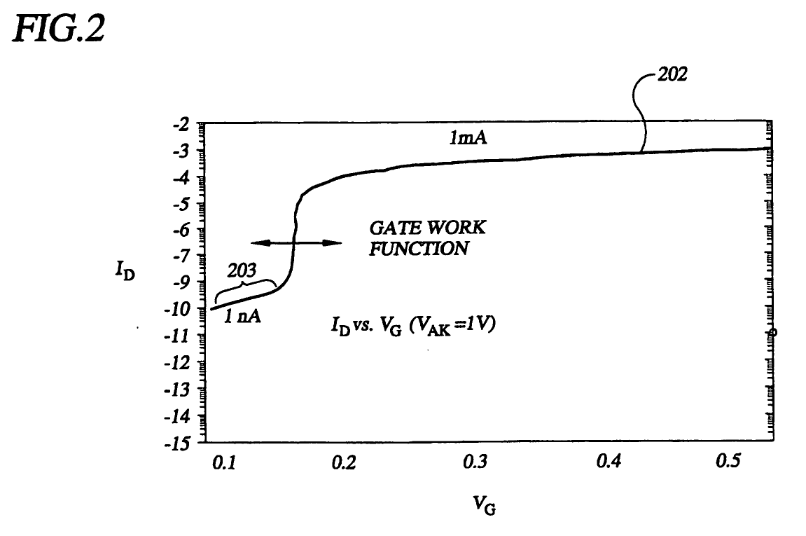

FIG. 2 shows an example computer simulation of drain current (I_{D}) vs. gate voltage (V_{G}) characteristics of such a PIN-based semiconductor device, in connection with another example embodiment of the present invention. I_{D} is shown on the vertical axis and V_{G} on the horizontal axis, with plot 202 being representative of a semiconductor device, such as the device 100 shown in FIG. 1A, with N+ region 112 as a drain for purposes of defining I_{D}. The subthreshold (portion 203 of plot 202) slope of the device implemented here is about 5 mv/decade using a germanium-containing substrate (e.g., substrate 107 of FIG. 1A) at a temperature of about 400K. The subthreshold slope obtained in the semiconductor device is a function of the material(s) used for the various components, the temperature of operation and other parameters such as doping and oxide thickness, and is chosen to fit the application to which the device is implemented.

A variety of materials are implemented for the substrate 107 of the device 100, in connection with various embodiments. In this regard, the approaches discussed herein may be implemented using materials such as silicon, germanium and heterostructures having different materials for end regions and intermediate regions. Referring to FIG. 1A, in one implementation, the intermediate region 114 is made up of two or more semiconductor materials in a graded or other arrangement. In another implementation, the substrate 107 includes one or more materials having a low bandgap and consequently high impact ionization coefficients. With these approaches, combinations of materials that exhibit low OFF-state leakage current and low breakdown voltage can be implemented.

In other example embodiments, referring again to FIG. 1A, the intermediate region 114 of the device 100 is doped to set the breakdown voltage (e.g., as shown and discussed in connection with doped region 115 and/or including other portions of the intermediate region). For example, by lightly doping the intermediate region 114 with an N-type impurity, a carrier channel is readily formed near the gate 130 with a high voltage being applied thereto (in this instance, forming an accumulation surface layer in the lightly doped intermediate region). Dopant concentrations that may be implemented in connection with this example embodiment include, for example, a concentration of N-type impurities in the range of between about 1×e¹² (i.e., 1 times e¹²)/cm³ to 1×e²⁰/cm³. Other dopant concentrations are implemented with the intermediate region 114 such that the concentration thereof is about 10⁻² to 10⁻⁸ less than the concentration of impurities at regions 110 and 112, for example with regions 110 and 112 having a dopant concentration of between about 10¹⁸/cm³ to 10²²/cm³. In one implementation, doping in the intermediate region 114 is added and/or increased to reduce the breakdown voltage, which correspondingly increases the electric fields required to cause breakdown. In another implementation, the intermediate region 114 is relatively lightly doped to minimize the band-to-band tunneling current.

In another implementation, the intermediate region 114 is doped such that the dopant concentration therein is graded. For instance, when doped with an N-type dopant, a higher concentration of N-type impurities is introduced nearer the N+ region 112, relative to the concentration of N-type impurities near the P+ region 110. With this approach, as similar to that discussed above in connection with the channel region 115, a relatively lower voltage can be applied to the gate 130 for switching the device 100 into a current passing (breakdown) mode.

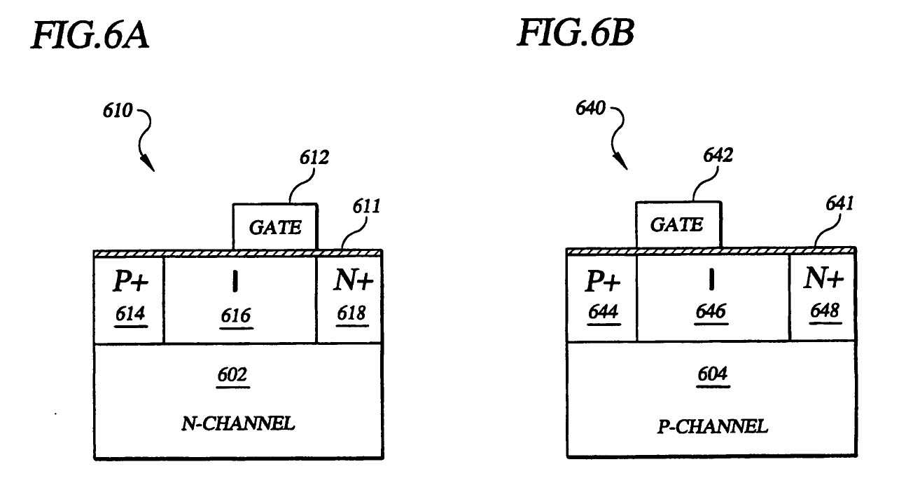

In another example embodiment, related to the embodiments discussed above in connection with FIG. 1A, the polarity of the end portions is switched, with region 110 having an N+ polarity and region 112 having a P+ polarity. In this instance, the operation of the device 100 is effected with opposite charges applied to the control port 130, relative to that discussed above. For example, a relatively large negative voltage is used to create a carrier channel region near the gate 130 and immediately adjacent region 112, and a relatively large positive voltage is used to accumulate N-type carriers from the N+ region into the intermediate region 114. The intermediate region 114 can also be correspondingly doped as discussed in the previous paragraph, for example to form a lightly P-doped portion thereof. This PMOS-type approach can be implemented in connection with other example embodiments herein, with a particular example discussed further below in connection with device 640 in FIG. 6B.

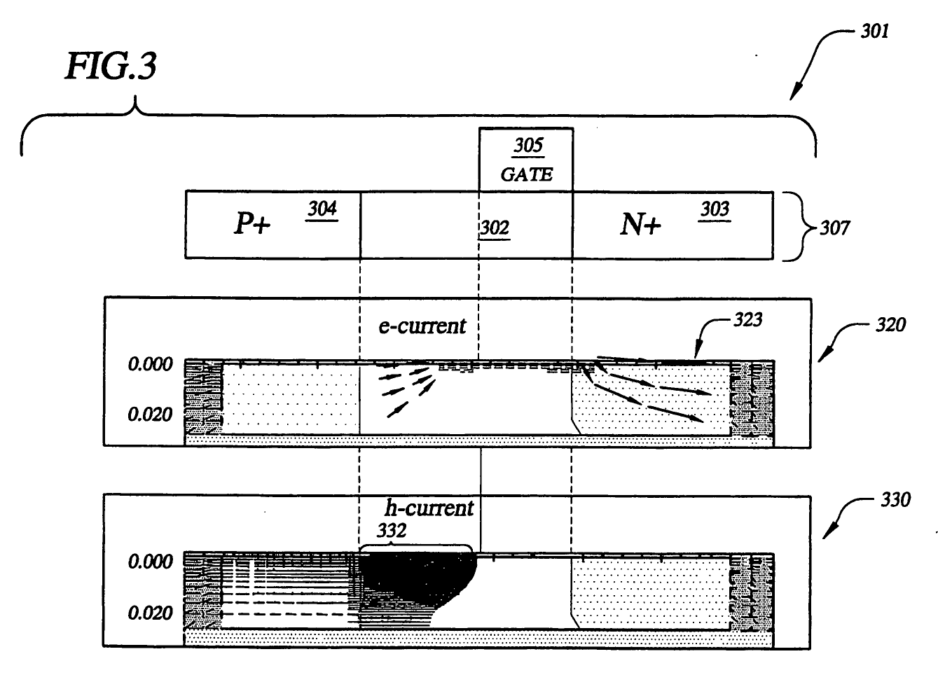

FIG. 3 shows an example computer simulation of physics characteristics for an example structure 301 and including steady-state electron and hole flow patterns 320 and 330, respectively, in response to the application of a high gate voltage, according to another example embodiment of the present invention. The structure 301 is illustrated with reference-numeral correspondence, for instance, to the device 100 shown in FIG. 1A, with the three-region body including oppositely-doped regions (analogous to source/drain regions) 303 and 304 and intermediate region 302 in a substrate 307, and with a gate 305 over the intermediate region and biased to define an accumulation surface channel closer to the junction at the N+ region 303. Dashed lines extending down from the structure 301 are for illustrative purposes and show correspondence along the metallurgical junctions defining the doping transitions at the borders of the intermediate region. In this example structure 301, the reverse-bias potential is held at about 1 V and the intermediate region 302 is intrinsic.

When a high gate voltage is applied (e.g., before an ON-state), an accumulation surface channel 321 is created in an intrinsic region 322 under the gate connected to the n+ region 323 as shown in carrier flow pattern 320. The ensuing accumulation of carriers in the intrinsic region 322 tends to reduce the effective length of the intrinsic region 322 over which the device's potential drops. More specifically, the electric field in the intermediate region 322 is increased and consequently the device breaks down due to an avalanche breakdown mechanism. In flow pattern 320, the carrier flow in the channel is shown as being predominantly electrons. The portion 332 of the intrinsic region 322 that is not below the gate breaks down due to the avalanche breakdown in the intermediate region and, hence, the current is predominantly a hole current. With this operation, due to the field-induced junction being created in the intermediate (intrinsic) region 322, the P+-I-N+ diode effectively changes to a P+-i-N-N+ diode, where lower case “i” refers to the effective length-modulated “intrinsic” region. Thus, the device approaches avalanche breakdown, for example, with an increased voltage at the gate (or increasing the magnitude of the potential between the P+ and N+ regions) increasing the electric field to cause avalanche breakdown.

When the voltage applied to the gate 305 is reduced, the concentration of accumulation carriers in the surface channel 321 decreases and, at a certain point, disappears altogether, with the ON state breakdown condition reverting back to the OFF state. Current flowing from the P+ source 304 to the N+ drain 303 is then primarily limited by reverse biased P-I-N junction leakage, which is a function of doping, temperature, carrier lifetime and other such factors.

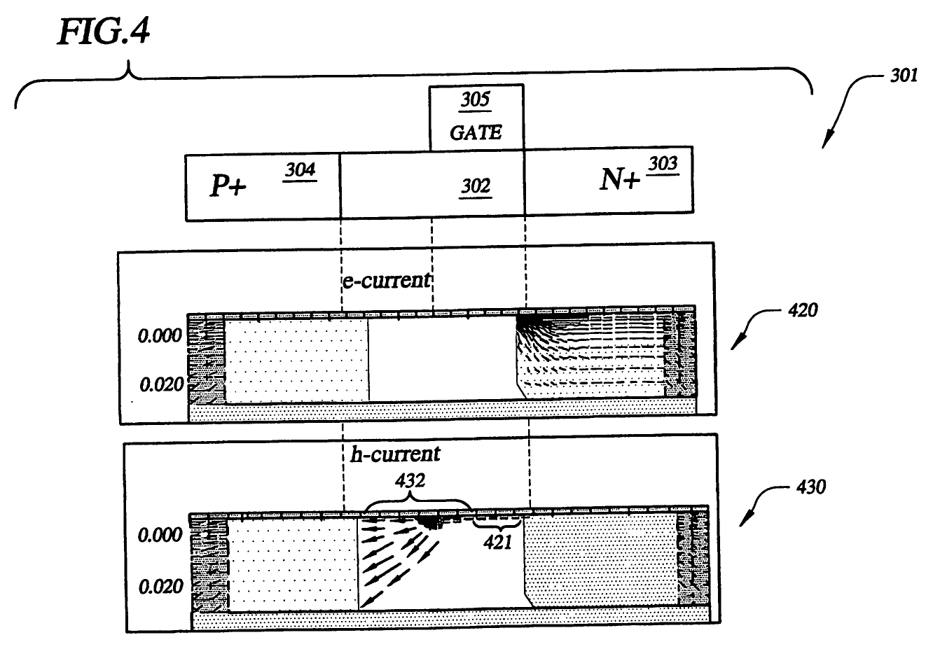

FIG. 4 shows a computer simulation of example physics characteristics for the example structure 301 of FIG. 3 and including steady-state electron and hole flow pattern illustrations 420 and 430, according to another example embodiment of the present invention. In this embodiment, the flow patterns 420 and 430 are shown using a negative voltage applied to the gate 305. If a sufficiently negative voltage is applied to the gate 305, the field-induced junction created in the intrinsic region 302 effectively changes the P+-i-N+ diode to a P+-P-N+ diode, where the effective “i” (intrinsic) region effectively disappears. This causes breakdown to occur in a portion 421 of the intrinsic region 302 close to the P-N+ junction. The carrier flow through most (portion 432) of the intrinsic region 302 is predominantly holes except for portion 421 where breakdown occurs.

FIG. 5 shows overall device characteristics of a semiconductor device that may, for example, be implemented in connection with the approaches discussed in connection with FIGS. 3 and 4 above. For purposes of discussion, “Mode 1” breakdown refers to breakdown occurring in connection with FIG. 3, and “Mode 2” breakdown refers to breakdown occurring in connection with FIG. 4, with a germanium-based substrate, such as that shown in FIG. 1A, at a temperature of about 400K. With this approach, the subthreshold slope for both Mode 1 and Mode 2 is about 5 mV/decade (positive or negative, respectively), which is much lower than kT/q. In one implementation, the characteristics shown are shifted about the V_{G} axis by tuning the gate workfunction. The gate workfunction can be tuned (i.e., set), for example, by doping the gate to set the bias presented to an intermediate region in response to a particular voltage applied to the gate and/or changing a dielectric material or thickness of dielectric between the gate and the intermediate region.

The Mode 1 breakdown (avalanche breakdown mechanism of a P+-i-N-N+ diode per discussion of FIG. 3) is used to achieve uniform fields over wider depletion regions and to assure low band-to-band tunneling currents. The Mode 2 breakdown (avalanche breakdown mechanism of a PN diode per discussion of FIG. 4) is used to achieve band-to-band tunneling mechanisms (soft breakdown) that also contribute to the current. The breakdown approach (e.g., Mode 1 or Mode 2) is selected for particular implementations, depending on the material(s), the doping and the temperature.

Using the approaches discussed above, the intrinsic delay in switching the device from the OFF-state to the ON-state (the time required to remove the excess carriers from the channel region) is relatively low. More specifically, the intrinsic delay is comparable to the transit time delay of the carriers, which is much lower, for example, than the switching speed of conventional FET implementations such as CMOS. In addition, the intrinsic delay in switching the device from the ON-state to the OFF-state is comparable to the seed-time associated with the generation of ionization current, which is also much lower, for example, than the delay associated with the switching speed of conventional CMOS.

Also according to the present invention, FIGS. 6A and 6B respectively show two example P-I-N devices 610 and 640, respectively identified to show analogous correspondence to N-channel and P-channel MOS devices. The devices 610 and 640, are operable, for example, in Mode 1 as discussed above in connection with FIGS. 3-5. Device 610 includes a P+ (source) region 614 and N+ (drain) region 618 separated by an intrinsic channel region 616, with a dielectric layer 611 and a gate 612 over the intrinsic channel region. Device 640 includes a P+ (drain) region 644 and an N+ (source) region 648 separated by an intrinsic channel region 646, with a dielectric 641 and a gate 642 over the intrinsic channel region.

The gates 612 and 642 are positioned for forming an N-channel or a P-channel device, with both gates being positioned respectively close to the (drain) regions 618 and 644 for each device, relatively to the positioning of the gate and the regions 614 and 648. In one implementation, the gate electrode of the (N-channel) device 610 and/or of the (P-channel) device 640 is chosen so that selected mechanisms occur at certain values of applied voltages. For instance, the workfunction of the gate electrodes of the devices 610 and 640 are chosen to be different to generate desired effects for the N-channel and P-channel approaches, respectively. With this approach, complementary devices can be generated, for example, to implement circuits such as inverters and other analog and digital devices, with combinations of the devices 610 and 640.

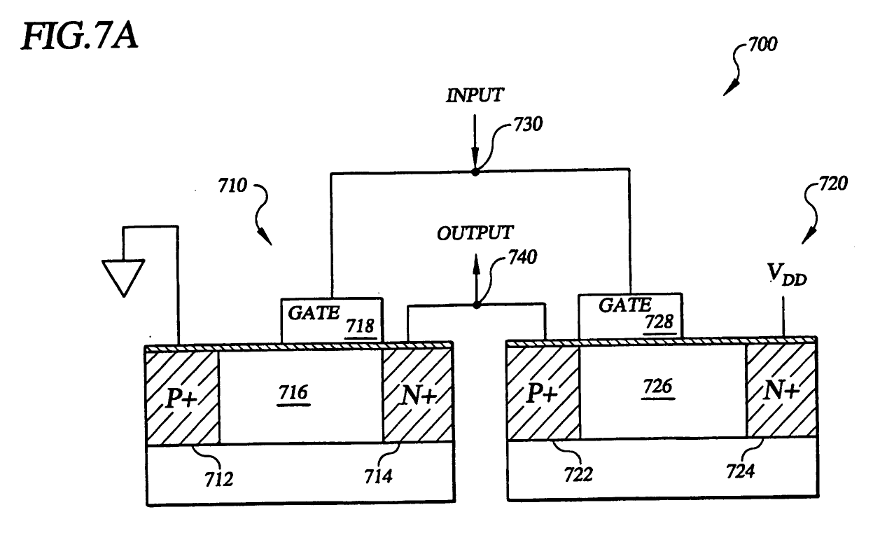

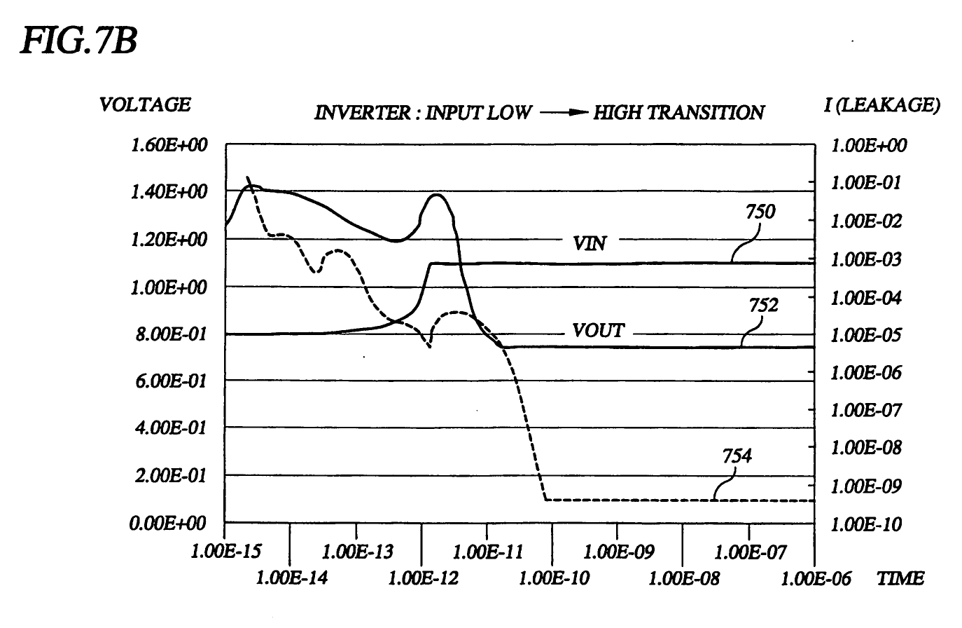

Consistent with the above discussion of FIGS. 6A and 6B, FIG. 7A shows an inverter circuit 700 including devices 710 and 720, according to another example embodiment of the present invention. The device 710 is an N-type device having P+ region 712 (coupled to ground), intermediate region 716 and N+ region 714, with a breakdown condition (and the corresponding conductance state) of the device being controlled via gate 718. The device 720 is a P-type device having P+ region 722, intermediate region 726 and N+ region 724 (coupled to V_{DD}), with a breakdown condition (and the corresponding conductance state) of the device being controlled with gate 728. In response to an input applied at node 730, the gates 718 and 728 couple a voltage bias to each of intermediate regions 716 and 726, respectively for controlling current flow and the output at node 740.

One manner in which the inverter circuit 700 can be operated is illustrated in connection with FIG. 7B, which shows a computer simulation of example transient operation when loaded by a 10 pF capacitor and when the input is switched from low-voltage (OFF-state) to high voltage, according to another example embodiment of the present invention. Voltage is shown on the vertical axis and time is shown on the horizontal axis. Plots 750, 752 and 754 represent the input voltage (V_{IN}), output voltage (V_{OUT}) and leakage current for the inverter, respectively. With this approach, the delay in driving the inverter is comparable to the delay in a CMOS inverter.

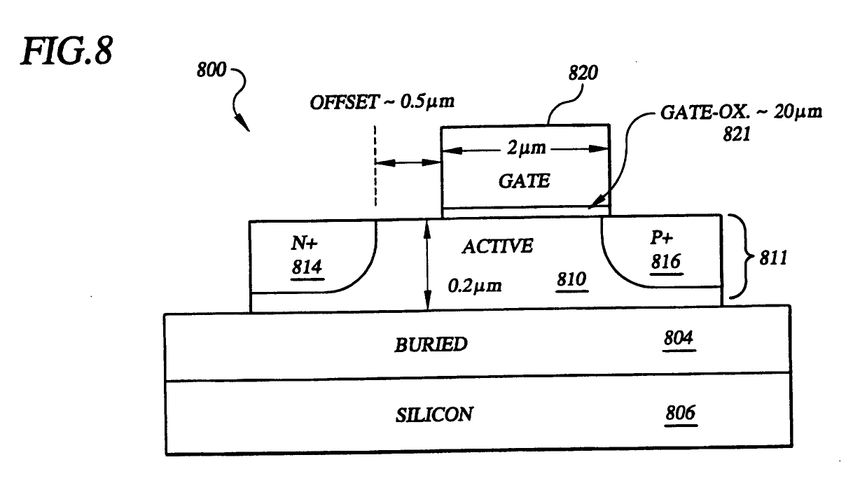

In a more particular example embodiment, FIG. 8 shows a P-channel device 800, having a body (e.g., a field-effect-transistor (FET) type body) combined with a center-offset gate electrode. The device 800 is fabricated, for example, using a silicon-on-insulator (“SOI”) wafer with conventional IC processing (making the process CMOS compatible). In one implementation, a conventional stepper tool is used for masking the device 800 for forming various features, with annealing carried out in a RTA at 1000° C. for about 40 seconds.

The P-channel device 800 includes a silicon base 802 with a buried insulator layer 804 having a thickness of about 0.4 μm. An active silicon region 811 includes an intermediate region 810 having a thickness of about 0.2 μm and flanked by a first end region 814 and a second end region 816. The first end region 814 is implanted to N+ polarity with an implant energy of between about 20 Kev and 50 Kev. The second end region 816 is implanted to P+ polarity using boron implantation (e.g., about a 1×e¹⁵/cm² dosage and an implant energy of about 50 Kev). The intermediate region 810 is kept relatively undoped and neutral (e.g., intrinsic), as compared to the first end region 814 and second end region 816. A gate-oxide layer 812, or gate dielectric, separates the intermediate region 810 from a gate electrode 820 and has a thickness between about 10-20 nanometers. In one implementation, the gate-oxide layer 812 is grown in dry ambient at about 900° C. for about 20 minutes and about 60 minutes respectively for 10 nanometer and 20 nanometer thickness. The gate electrode 820 is between about 0.8 μm 2.0 μm in length and between about 1 μm to 10 μm in width.

The gate electrode 820 is center-offset over the intermediate region 810 in a range from about 0.1 μm to about 0.6 μm from center (e.g., as shown, the gate is offset towards the P+ doped end region 816). In various implementations, the intermediate region 810 is made of germanium and/or other lower bandgap materials. The P-channel device 800 is adapted to effect modulation of breakdown voltage in the intermediate region 810 for current switching, for example, as discussed above.

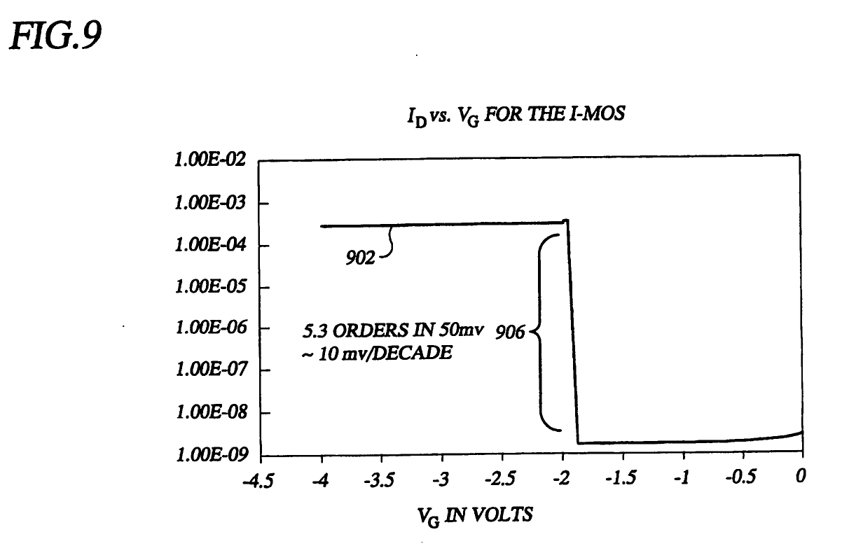

FIG. 9 shows example characteristics for an example P-channel device, such as the device 800 shown in FIG. 8, according to another example embodiment of the present invention. Current (I_{D}) is on the vertical axis and voltage (V_{G}) is on the horizontal axis, with the response of the device shown with plot 902. Portion 906 of the plot 902 shows the subthreshold slope of the device, here being about 10 mv/decade. The relatively large actual (versus effective) length of the intermediate region 810 and the device's abrupt switching to the ON-state is used for implementing such an abrupt subthreshold slope.

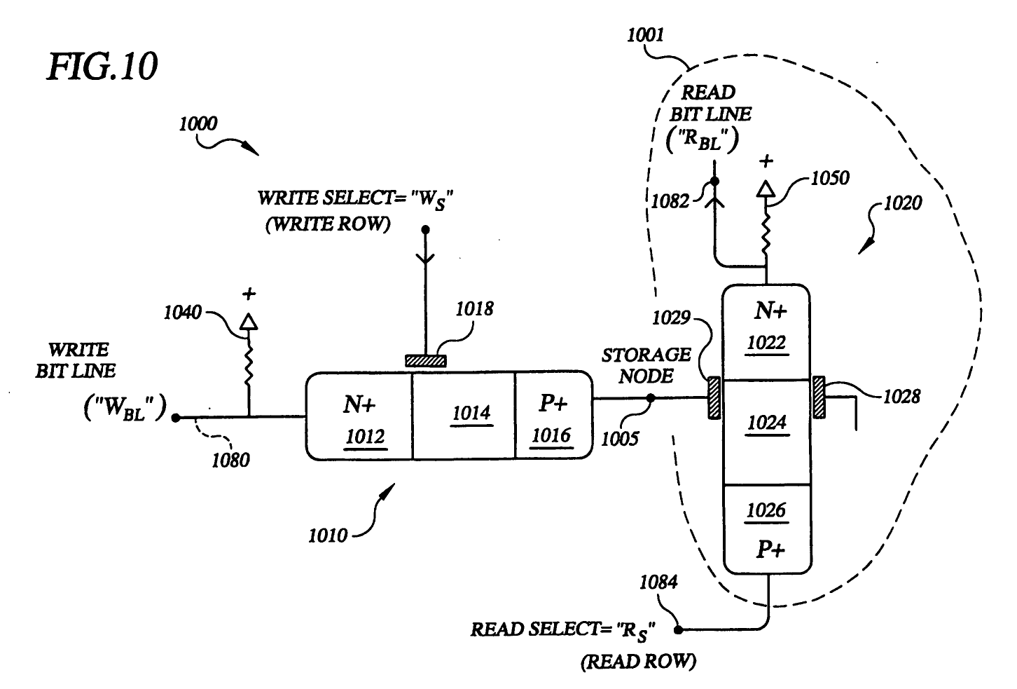

FIG. 10 shows a circuit device 1000 including two devices 1010 and 1020, according to another example embodiment of the present invention. The device 1010, including N+ region 1012 and P+ region 1016 separated by an intermediate region 1014 having a gate 1018 coupled thereto, is configured and operated to control the voltage level at a storage node 1005. The device 1020, including N+ region 1022 and P+ region 1026 separated by an intermediate region 1024, is adapted for passing current as a function of a breakdown mode controlled by the gate 1029 coupled to the voltage at the storage node. Optionally, the device 1020 is a dual-gate device having a second gate 1028 for controlling the switching of the device into a breakdown mode. Each of the devices 1010 and 1020 are coupled at their respective N+ regions 1012 and 1022 to pull-up resistor circuits 1040 and 1050, respectively, for holding the N+ regions high.

The level at the storage node 1005 is controlled, for example, using an approach similar to that discussed in connection with device 100 in FIG. 1A. The pull-up resistor 1040 is implemented for maintaining an N+ region 1012 high, which is also coupled to a write bit line 1080. A write select signal is applied to a gate 1018 for controlling the conductance state of the device 1010 (and the corresponding voltage at storage node 1005).

For a write “one” operation, the write bit line 1080 is held high and a high positive voltage is applied to the gate 1018. When the level of the storage node 1005 is low (i.e., a “zero”), a field-induced junction in the intermediate region 1114 created by the gate 1018 enables the device to switch into an avalanche breakdown condition. Optionally, a breakdown condition is instead created in the intermediate region 1114 using a negative voltage on the gate 1018 as discussed, for example, in connection with FIG. 5 above. The storage node 1005 is thus charged to a high level. Optionally, the P+ region 1016 is pulled low (e.g., −0.5 V), for example, using a diode coupled to the storage node 1005, to create a potential drop across the N+ region 1012 and the P+ region 1016.

For a write “zero” operation, the write bit line 1080 is held low to switch the device 1010 into a forward biased condition. Optionally, a voltage is applied to the gate 1018 to enhance the pull of charge from the storage node 1005 (and P+ region 1016). In each of the write “one” and “zero” operations, the P+ region 1026 of device 1020 is optionally held low with the N+ region 1022 held high so that the device is held in a reverse-biased condition.

The read out of the level at the storage node 1005 is effected as follows, using the circuit portion 1001. The write bit line 1080 is allowed to float (or held high) and the gate 1018 is held at about zero volts so the device 1010 is held in a reverse biased condition. A read select node 1084 coupled to the P+ region 1026 is dropped in voltage, increasing the voltage drop between the P+ region and the N+ region 1022 (with the pull-up resistor circuit 1050 holding N+ region high). When the voltage level at the storage node 1005 is high and the P+ region is pulled low, the gate 1029 couples a high voltage to the intermediate region 1024 and the device 1020 is switched into an avalanche breakdown condition. A read bit line 1082 drops in voltage, which is detected and used as an indication of the storage node 1005 being held high. When the level at the storage node 1005 is about zero, the drop in voltage level at the P+ region 1026 is insufficient to effect an avalanche condition without a positive voltage being applied via the gate 1029.

Optionally, instead of or in addition to dropping the voltage level at the read select node 1084, a second gate 1028 is used to apply a positive voltage to the intermediate region 1024 for reading the storage node 1005. The voltage applied to the second gate 1028 is selected such that an avalanche breakdown condition in the intermediate region 1024 occurs only when the level at the storage node 1005 (and correspondingly at the gate 1029) is high. In this regard, for example with the P+ region 1026 being held to ground, a voltage is applied to the gate 1028 while sensing any change in voltage at the read bit line 1082. If a change in voltage is sensed when the gate 1028 is held high, a high level (e.g., logical one) at the storage node 1005 is detected; if no change is sensed, a low level (e.g., logical zero) at the storage node 1005 is detected.

In another particular implementation, the circuit portion 1001 in FIG. 10 is separately implemented, without the remaining portion of the circuit 1000, for example as a stand-alone circuit or using another circuit to control the voltage level at the storage node 1005.

The device 1000 shown in FIG. 10 can be implemented in a variety of other manners. For example, as discussed above, the individual devices 1010 and 1020 can be switched to PMOS type and NMOS type devices, as shown and discussed above, for example, in connection with FIGS. 1 and 6. The devices 1010 and 1020 can also be switched using Mode 1 or Mode 2, as discussed in connection with FIG. 5, with the voltage level being applied to the gates (and at which the storage node 1005 is held) being correspondingly controlled. Furthermore, the device 1000 can be implemented in memory applications such as arrays, data storage circuits and others, for example, such as shown in U.S. Pat. No. 6,021,064 to McKenny et al., which is fully incorporated herein by reference.

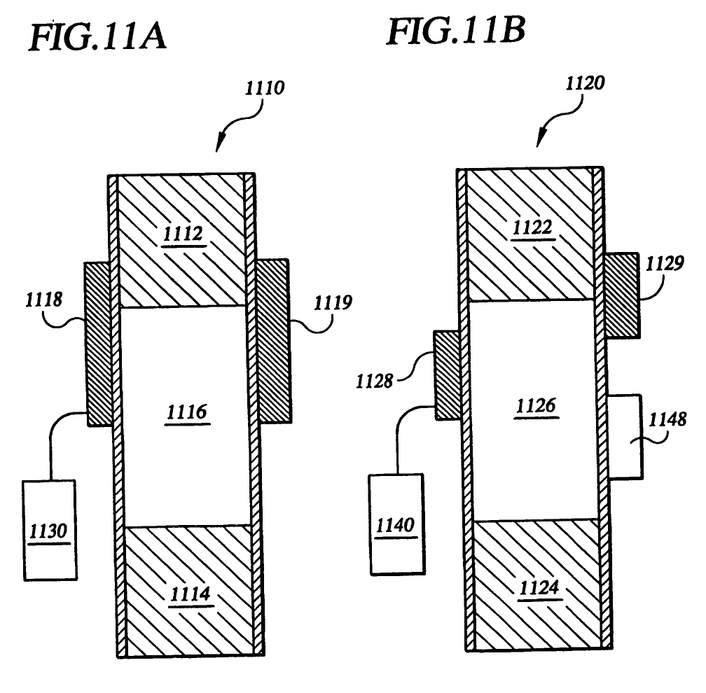

FIG. 11A shows a dual-gate implementation of a semiconductor device 1110, according to another example embodiment of the present invention. The device 1110 includes end portions 1112 and 1114 having opposite polarity and separated by an intermediate region 1116 of relatively neutral polarity. Gates 1118 and 1119 are adapted for applying a voltage to the device 1110 for controlling current flow therein. Depending upon the voltage applied to each of the gates 1118 and 1119, as well as the polarities of the end portions 1112 and 1114, current flow in the intermediate region 1116 can be controlled in a variety of manners. As shown, the device 1110 is arranged vertically; however, a horizontal arrangement, for example as shown in FIG. 1A, is also implemented for a variety of applications.

In one implementation, the gate 1118 is used for switching the device 1110 into a breakdown mode, with the gate 1119 being operated by a control circuit 1130 for temperature control. For example, when the operating temperature of the device 1110 increases, the voltage drop across the end portions 1112 and 1114 at which breakdown occurs in the intermediate region 1116 changes. To effect breakdown consistently in the intermediate region 1116 with voltage applied to the gate 1118, the gate 1119 is operated to apply a voltage as a function of temperature, for example, by applying a voltage to counter breakdown voltage reductions that might otherwise occur in response to increases in temperature. More specifically, voltages presented at the gate 1119 can be used to create an electric field in the intermediate region 1116 that counters the effect of the field created by the gate 1118, for example, as discussed above in connection with FIG. 1A. Depending upon the breakdown mode being used, the polarity of the signal applied to the gate 1119 is selected accordingly (e.g., with an N+ doped region 1112 and a P+ doped region 1114, positive for Mode 1, negative for Mode 2).

As an option, the control circuit 1130 includes a temperature feedback loop. In one instance, the feedback loop is coupled to an output of the device 1110 (or to a similar device used for feedback purposes) to detect a temperature-related response thereof. In response to the coupled output from the feedback loop, the control circuit 1130 applies a voltage to the gate 1118.

In another implementation, one of gates 1118 and 1119 is used as a set-up gate, for example, to apply a relatively constant bias to the intermediate region 1116. The other of the gates 1118 and 1119 not used as a set-up gate is used to control breakdown in the intermediate region. With this approach, a lower voltage is required for breakdown, with a set-up gate holding the device 1110 near a breakdown state and a relatively small voltage being added to push the device 1110 into breakdown mode.

In another implementation, the device 1110 is implemented as a NAND gate, with both gates 1118 and 1119 having similarly-biased inputs thereto effecting a breakdown condition in the intermediate region 1116. For example, when both gates have a high positive voltage applied thereto, with region 1112 being N+ and region 1114 being P+, the device behaves similarly to the device 100 in FIG. 1 with a high positive voltage applied to get 130.

FIG. 11B shows another dual-gate implementation of a semiconductor device 1120 similar to that shown in FIG. 11A but having offset gates, according to another example embodiment of the present invention. The device 1120 includes end regions 1122 and 1124 having opposite polarity and separated by an intermediate region 1126. Gates 1128 and 1129 are operable, for example, in a manner consistent with that discussed in connection with gates 1118 and 1119 in FIG. 11A. The device 1120 may similarly be implemented as a NAND gate, and optionally includes a control circuit 1140.

In one implementation, another gate 1148 is located adjacent to the gate 1129, in lieu of or in addition to the gate 1128 (and, in the former case, also optionally coupled to the controller 1140, e.g., for temperature control). The gate 1148 can be implemented, for example, with temperature control, as a NAND gate or as a set-up gate. The workfunction of the gate 1148 is optionally different from the workfunction of the gate 1129, for example, to effect a lesser or greater field in response to a similar voltage being applied thereto. For instance, when used as a set-up gate, gate 1148 can be implemented with a relatively smaller workfunction, relative to the gate 1129, such that similar voltage applied to both gates does not switch the device 1120 into a breakdown mode when applied only to gate 1148. This relative workfunction approach is also applicable to other multiple gate applications in connection with other embodiments discussed herein.

In another implementation, the device 1120 in FIG. 11B is arranged horizontally, for example similar to the device 100 in FIG. 1A. In one instance, the device 1120 utilizes gates 1129 and 1148, without gate 1128, such that the side nearest the gate 1128 (shown extending vertically) is disposed on a substrate such as silicon, germanium or an insulative layer. In another instance, the device 1120 includes the gate 1128, disposed underneath intermediate region 1126 in such a horizontal arrangement. A variety of other arrangements (non-horizontal, non-vertical or combinations thereof) of the device 1120 are also implemented for a variety of applications.

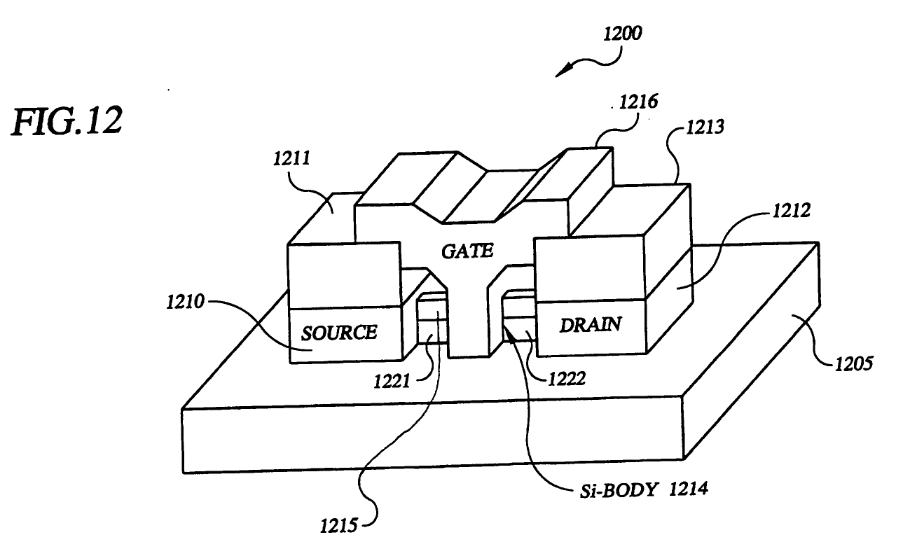

FIG. 12 shows a FIN type device 1200, according to another example embodiment of the present invention. In this example, oppositely-doped regions 1210 and 1212 (analogous to source and drain regions) are separated by a relatively thin fin region 1214, all disposed on a substrate 1205 and defining a P-I-N body. A first portion 1222 of the fin 1214 immediately adjacent the gate 1216 and region 1212 is doped to a polarity and concentration similar to that of the region 1212. A second, relatively undoped intermediate portion 1221 of the fin 1214 extends under the gate 1216 and to region 1210. Relative to regions 1210, 1222 and 1212, the intermediate portion 1221 has a lightly doped or intrinsic-type composition. Insulative material 1211, 1213 and 1215 is respectively formed over the P-I-N body regions 1210, 1212 and 1214. A gate 1216 is formed over the fin region 1214 and on vertical portions thereof and adapted to couple a signal to the fin region for controlling breakdown voltage therein, for example, using an approach similar to that discussed in connection with FIG. 1A above.

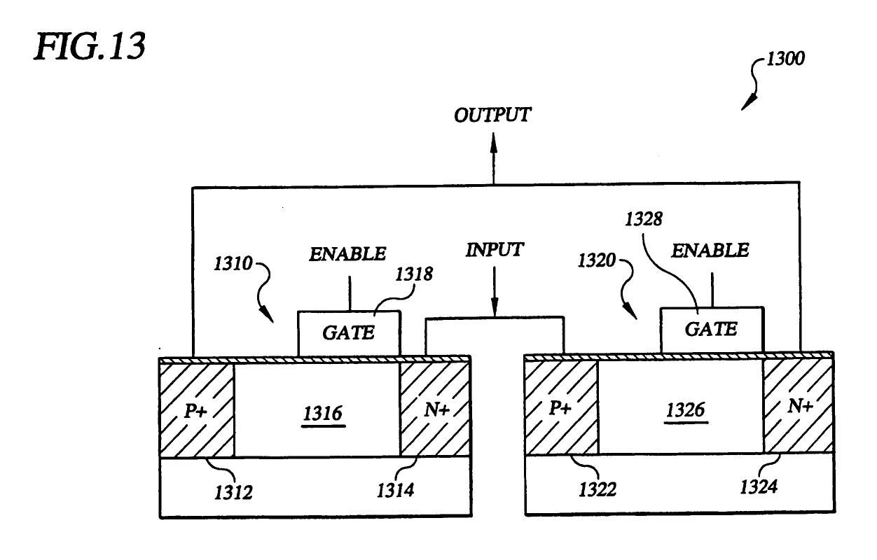

FIG. 13 shows another implementation for a semiconductor device, with a pass device 1300 including two parallel-operating P-I-N type circuits 1310 and 1320, according to another example embodiment of the present invention. Using the previously-discussed Mode 1 as example application, like an N-channel device the circuit 1310 is activated in response to a relatively high positive voltage presented at gate 1318 (similar to FIG. 1A). The circuit 1320 (acting like a P-channel device) is activated in response to a relatively high negative voltage presented at gate 1328. The gates 1318 and 1328 are adapted to respectively couple an enable signal (presented in inverted form to the gate 1328) to the intermediate regions 1316 and 1326 for respectively controlling the conductance state of the circuits 1310 and 1320. An equivalent circuit (not shown) would replace the P-I-N type circuit 1320 with another P-I-N type circuit 1310 and using the enable signal (non-inverted) presented to both gates.

The devices shown herein have a variety of implementations, with the exemplary figures showing a few examples thereof. In various implementations, a P-I-N type device, such as those discussed herein, is formed laterally (e.g., similar to CMOS), vertically (with the various doped materials stacked one above the other) and/or in another arrangement. In addition, other implementations involve SOI, non-SOI or a combination of SOI and non-SOI structures. In addition, gate dielectrics used may include materials such as oxide, nitride or another dielectric material. Moreover, in other implementations, gate electrodes discussed herein are made of material such as n+ polysilicon, p+ polysilicon, metal, other conductive material or a combination thereof.

While the present invention has been described with reference to several particular example embodiments, those skilled in the art will recognize that many changes may be made thereto without departing from the spirit and scope of the present invention, which is set forth in the following claims.

What is claimed is:

1. A semiconductor device, comprising:
a multi-region body including a first region dominated by a first polarization that extends to a first junction, a second region dominated by an opposite polarization that extends to a second junction, and an intermediate region having a length extending from the first junction to the second junction; and
a gate capacitively-coupled to the body and adapted for using a control signal, when the body is reversed biased, to modulate the length of the intermediate region by changing a concentration of carriers in the intermediate region.

2. The semiconductor device of claim 1, wherein the gate is further adapted to cause the device to transition between a current-conducting state in which the device is in an avalanche breakdown condition and a current-blocking state.

3. The semiconductor device of claim 1, further including means for modulating an electric field within the body to cause the device to transition between a current-conducting state in which the device is in avalanche breakdown condition and a current-blocking state.

4. The semiconductor device of claim 1, wherein a relatively high bias voltage at the gate maintains the device in a current-conducting state in which the device is in an avalanche breakdown condition, and wherein a relatively low bias voltage at the gate maintains the device in a current-blocking state.

5. The semiconductor device of claim 4, wherein the relatively high bias voltage shortens the effective length of the intermediate region.

6. The semiconductor device of claim 1, wherein a relatively low bias voltage at the gate maintains the device in a current-conducting state in which the device is in an avalanche breakdown condition, and a relatively-high bias voltage at the gate maintains the device in a current-blocking state.

7. The semiconductor device of claim 6, wherein the relatively low bias voltage shortens the effective length of the intermediate region.

8. The semiconductor device of claim 1, wherein the gate is located at least preponderantly over the second region.

9. The semiconductor device of claim 1, wherein the gate is located at least preponderantly over the intermediate region.

10. The semiconductor device of claim 1, wherein the gate is located to provide a surface channel nearer the second junction than the first junction.

11. The semiconductor device of claim 1, wherein when the body is reversed-biased, the first region is maintained at a relatively lower voltage level than the second region, the difference in potential of the first and second regions being sufficient to cause a breakdown condition in the intermediate region in response to the control signal modulating the length of the intermediate region and thereby reducing the distance across the intermediate region over which the potential drops.

12. The semiconductor device of claim 1, wherein the intermediate region has a polarity that is neutral relative to the polarity of the first and second regions.

13. The semiconductor device of claim 12, wherein the intermediate region is lightly doped to achieve the polarization of one of the first and second regions, the intermediate region having a substantially lower dopant concentration level, relative to said one of the first and second regions.

14. The semiconductor device of claim 12, wherein the intermediate region is substantially intrinsic.

15. The semiconductor device of claim 1, wherein the gate is further adapted to cause the device to transition between a current-conducting state in which the device is in an avalanche breakdown condition and a current-blocking state in which substantially no leakage current passes between the first and second regions.

16. The semiconductor device of claim 1, further comprising a controller coupled to the gate and adapted for applying the control signal to change the concentration of carriers in the intermediate region.

17. The semiconductor device of claim 1, wherein the gate is further adapted to increase an electric field in the intermediate region and for causing an avalanche breakdown condition.

18. A semiconductor device comprising:
a multi-region body including a P-type region, an N-type region and an intermediate region having a first junction with the P-type region and a second junction with the N-type region, the body adapted to be reverse biased across the P-type and N-type regions;
a gate coupled via an intervening gate dielectric material to the intermediate region, and offset to present an electric field substantially at only one of the two junctions; and
the gate, the P-type region and the N-type region being adapted and controllable to switch the device between at least two stable conductance states in response to a voltage-bias control signal applied to the gate.

19. The semiconductor device of claim 18, wherein the device is switched between a high-resistance conductance state and a low-resistance conductance state as a function of an avalanche breakdown condition at a field-induced junction in the intermediate region.

20. The semiconductor device of claim 18, wherein the intermediate region has a length that separates the first and second junctions sufficiently to permit the avalanche breakdown condition before another breakdown condition when the body is reverse biased.

21. A memory circuit comprising:
a data storage node;
a multi-region body including a first region dominated by a first polarization that extends to a first junction, a second region dominated by an opposite polarization that extends to a second junction, and an intermediate region having a length extending from the first junction to the second junction; and
a gate coupled to the body via an intervening dielectric material and offset for using a control signal, when the body is reversed biased, to present an electric field substantially at only one of the first and second junctions, the body responding to the electric field by switching from a stable conductance state to a current-conducting state in which the body is in an avalanche breakdown condition and current passes between the data storage node and the body.

22. The memory circuit of claim 21, wherein the body and the gate are adapted to access data stored at the data storage node as a function of the avalanche breakdown condition.

23. The memory circuit of claim 21, wherein the body and the gate are adapted to read data from the data storage node as a function of the avalanche breakdown condition.

24. The memory circuit of claim 21, wherein the body and the gate are adapted to write data to the data storage node as a function of the avalanche breakdown condition.

25. The memory circuit of claim 21, wherein a charge at the data storage node is maintained by controlling the body in a reverse biased condition.

26. The memory circuit of claim 21, wherein the body and the storage node are adapted to drain a charge at the storage node in response to the body being placed in a forward biased condition.

27. A memory circuit comprising:
a data storage node;
a multi-region body including a first region dominated by a first polarization that extends to a first junction, a second region dominated by an opposite polarization that extends to a second junction, and an intermediate region having a length extending from the first junction to the second junction; and
a gate coupled to the body via an intervening dielectric material and offset for using a control signal, when the body is reversed biased, to present an electric field substantially at only one of the first and second junctions, the body responding to the electric field by switching from a stable conductance state to a current-conducting state in which the body is in an avalanche breakdown condition and current passes through the body as a function of a charge at the data storage node.

28. The memory circuit of claim 27, wherein the data storage node is coupled to the gate, the gate responding to a charge at the data storage node by presenting the electric field.

29. The memory circuit of claim 27, further comprising a sense device coupled to the body and adapted to detect data stored at the data storage node in response to current passing through the body.

30. A memory circuit comprising:
a data storage node;
first and second multi-region bodies, each body including a first region dominated by a first polarization that extends to a first junction, a second region dominated by an opposite polarization that extends to a second junction, and an intermediate region having a length extending from the first junction to the second junction;
a first gate coupled to the first body via an intervening dielectric material and offset for using a control signal, when the first body is reversed biased, to present an electric field substantially at only one of the first and second junctions of the first body, the first body responding to the electric field by switching from a stable conductance state to a current-conducting state in which the first body is in an avalanche breakdown condition and current passes between the data storage node and the first body; and
a second gate coupled to the data storage node and to the second body via an intervening dielectric material and adapted for using a charge at the data storage node, when the second body is reversed biased, to modulate an electric field in the intermediate region of the second body, the second body responding to the electric field by switching from a stable conductance state to a current-conducting state in which the second body is in an avalanche breakdown condition and current passes through the second body.

31. The memory circuit of claim 30, further comprising a sense device coupled to the second body and adapted to detect data as a function of sensed current passing through the second body, and wherein the second gate is further adapted to influence an electric field substantially at only one of the first and second junctions.

32. A semiconductor device, comprising:
a multi-region body including a first region dominated by a first polarization that extends to a first junction, a second region dominated by an opposite polarization that extends to a second junction, and an intermediate region having a length extending from the first junction to the second junction; and
first and second gates coupled to the body via intervening dielectric material and adapted for using control signals, when the body is reversed biased, to present an electric field at one of the first and second junctions, the body responding to the electric field by switching from a stable conductance state to a current-conducting state in which the body is in an avalanche breakdown condition.

33. The semiconductor device of claim 32, wherein the first gate is adapted to capacitively couple a first voltage-bias control signal to the body to accumulate carriers immediately adjacent to said one of the first and second junctions, the body being held in a steady state without the avalanche breakdown condition occurring absent a similarly-biased control signal capacitively coupled to the body from the second gate.

34. The semiconductor device of claim 32, wherein the first gate is adapted to capacitively couple a first voltage-bias control signal to the body to accumulate carriers immediately adjacent to said one of the first and second junctions, the body switching to the current-conducting state in response to a second voltage-bias control signal being capacitively coupled to the body, the first and second voltage-bias control signals being of similar bias.

35. The semiconductor device of claim 32, wherein the second gate is responsive to temperature and adapted to apply a control signal to the body that counters temperature-related effects that alter the creation of the avalanche breakdown condition in response to a control signal being applied by the first gate.

36. The semiconductor device of claim 35, wherein the second gate is adapted to apply the control signal to maintain a threshold voltage level in the intermediate region, the threshold voltage being a minimum amount of additional voltage applied to the intermediate region for causing the avalanche breakdown condition.

37. An inverter circuit comprising:
first and second multi-region bodies, each body having a highly-doped P-type region that extends to a first junction, a highly-doped N-type region that extends to a second junction, and an intermediate region having a neutral polarity relative to the P-type and N-type regions and having a length extending from the first junction to the second junction, the N-type region of the first body and the P-type region of the second body being coupled to a common output node;
first and second gates respectively capacitively coupled to the first and second bodies and each adapted, when the bodies are reversed biased, to modulate the length of the intermediate regions of the respective bodies by changing a concentration of carriers in the respective intermediate regions; and
an input node coupled to the first and second gates, wherein a change in input signal applied to the input nodes causes an inverted response in an output signal at the output node.

38. A semiconductor device comprising:
a relatively thin intermediate region defined by sides including an upper portion and a sidewall portion;
a first region dominated by a first polarization that extends to a first junction with the intermediate region;
a second region dominated by a second polarization that extends to a second junction with the intermediate region; and
a gate extending around and capacitively coupled to at least two sides of the intermediate region for coupling a voltage to the intermediate region, when the first and second regions are reversed biased, to present an electric field substantially at only one of the first and second junctions, the device responding to the electric field by switching from a stable conductance state to a current-conducting state in which the body is in an avalanche breakdown condition and current passes through the intermediate region.

39. A semiconductor device, comprising:
a multi-region body including a first region dominated by a first polarization that extends to a first junction, a second region dominated by an opposite polarization that extends to a second junction, and an intermediate region having a length extending from the first junction to the second junction; and
means for presenting, when the body is reversed biased, an electric field at the first junction, the body responding to the electric field by switching from a stable conductance state to a current-conducting state in which the body is in an avalanche breakdown condition and current passes in the body.

40. A method for operating a semiconductor device having a multi-region body including a first region dominated by a first polarization that extends to a first junction, a second region dominated by an opposite polarization that extends to a second junction and an intermediate region having a length extending from the first junction to the second junction, the method comprising:
capacitively coupling an electric field to the body at the first junction, when the body is reversed biased, and causing the body to switch from a stable conductance state to a current-conducting state in which the body is in an avalanche breakdown condition and current passes in the body.

41. The method of claim 40, further including modulating an electric field within the body to cause the body to transition between a current-conducting state in which the body is in avalanche breakdown condition and a current-blocking state in which substantially no current flows between the first and second regions.

42. A method for manufacturing a semiconductor device including a multi-region body, the method comprising:
doping a first region of the body to a first polarization that extends to a first junction;
doping a second region of the body to an opposite polarization that extends to a second junction, the first and second junctions defining a length of an intermediate region extending between the first and second regions; and
forming a gate capacitively-coupled to the body and arranged with the body for using a control signal to present, when the body is reversed biased, an electric field at the first junction that causes the body to switch from a stable conductance state to a current-conducting state in which the body is in an avalanche breakdown condition and current passes in the body.

43. A semiconductor device, comprising:
a multi-region body having an upper surface and including a first region dominated by a first polarization that extends to a first junction, a second region dominated by an opposite polarization that extends to a second junction, and an intermediate region having an upper portion over a lower portion and a length extending from the first junction to the second junction;
a gate capacitively-coupled to the body and adapted for using a control signal, when the body is reversed biased, to modulate the length of the intermediate region by changing a concentration of carriers in the intermediate region and thereby causing the device to transition between a current-conducting state in which the device is in an avalanche breakdown condition and a current-blocking state; and
the avalanche breakdown condition occurring in the lower portion of the intermediate region, the upper portion of the intermediate region arranged to inhibit hot carriers from the lower portion reaching the upper surface in a current-conducting state.
